(19) United States
(12) Patent Application Publication
(10) Pub. No.: US 2026/0025923 A1
(43) Pub. Date: Jan. 22, 2026

(54) PRINTED CIRCUIT BOARD BACKDRILL QUALITY VERIFICATION

(71) Applicant: DELL PRODUCTS L.P., Round Rock, TX (US)

(72) Inventors: Chang-Kai Chu, Zhongli District (TW); Ching-Huei Chen, Taoyuan City (TW); Vijendera Kumar, Bangalore (IN); Bhyrav Mutnury, Round Rock, TX (US)

(21) Appl. No.: 18/775,324

(22) Filed: Jul. 17, 2024

(51) Int. Cl. H05K 1/11; G01B 7/26; G01R 31/28; H05K 1/02; H05K 3/40

(52) U.S. Cl. CPC H05K 1/115; G01B 7/26; G01R 31/2808; H05K 1/0268; H05K 1/0298; H05K 3/4038; H05K 2203/0207

(57) ABSTRACT

A printed circuit board, comprising a via configured to provide electrical connectivity between layers of the printed circuit board and having at least a portion of the via backdrilled resulting in a backdrill hole. The printed circuit boar also includes a test coupon configured to determine whether the backdrill hole is according to a specification.

### FIELD OF THE DISCLOSURE

The present disclosure generally relates to information handling systems, and more particularly relates to printed circuit board backdrill quality verification.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A printed circuit board, comprising a via configured to provide electrical connectivity between layers of the printed circuit board and having at least a portion of the via backdrilled resulting in a backdrill hole. The printed circuit boar also includes a test coupon configured to determine whether the backdrill hole is according to a specification.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of an information handling system, according to an embodiment of the present disclosure;

FIGS. 2-5 are cross-section views of printed circuit boards, according to an embodiment of the present disclosure;

FIG. 6 is a block diagram of an information handling system, according to an embodiment of the present disclosure;

FIGS. 7-10 are cross-section views of printed circuit boards, according to an embodiment of the present disclosure;

FIGS. 11-12 are flowcharts of a method for printed circuit board backdrill quality verification, according to an embodiment of the present disclosure; and

FIG. 13 is a block diagram of an information handling system, according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

Printed circuit boards (PCBs) are typically included with hardware components of an information handling system. PCBs may include multiple layers wherein along each layer, conductive members are routed. These conductive members are typically referred to as traces. Vias, which are disposed generally perpendicular to the PCB, are used to provide electrical connectivity between the traces on different layers of the PCB. Vias may be backdrilled to remove via stubs. However, PCB backdrilling issues occur due to various factors, such as human error during manufacturing setup. Other backdrilling issues, such as abnormal equipment operation and incorrect PCB core thickness may also occur. These backdrilling issues may result in unwanted via stub lengths resulting in undesired resonance which can affect signal quality. The PCB may also include test coupons for evaluating PCB characteristics, as well as for quality control and operability before the PCB goes into production. For example, the test coupons may be used to evaluate the backdrilling process, also referred to as controlled depth drilling, of a PCB manufacturer, such as whether the PCB manufacturer is able to remove via stub properly according to specifications. Accordingly, the present disclosure provides a system and method to determine whether the backdrill is within specification.

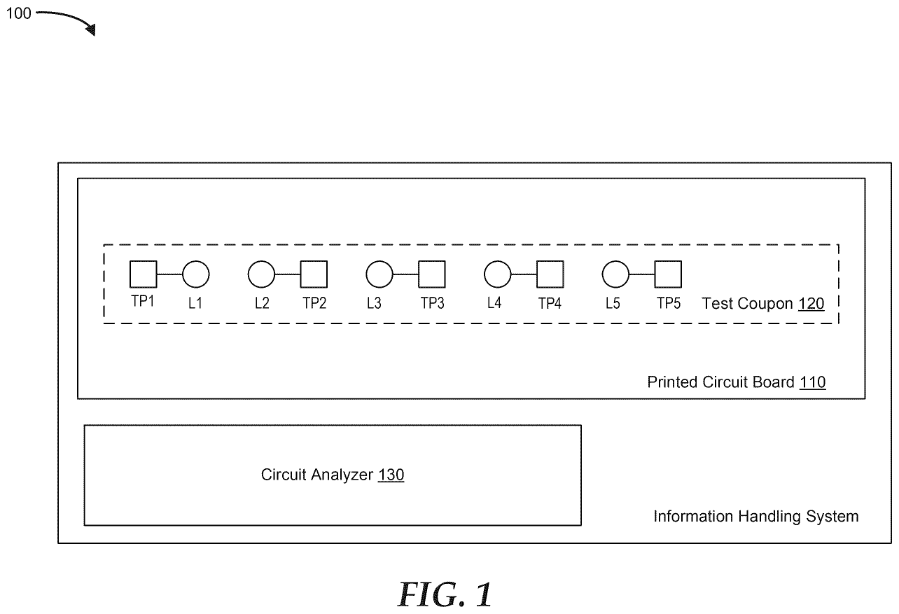

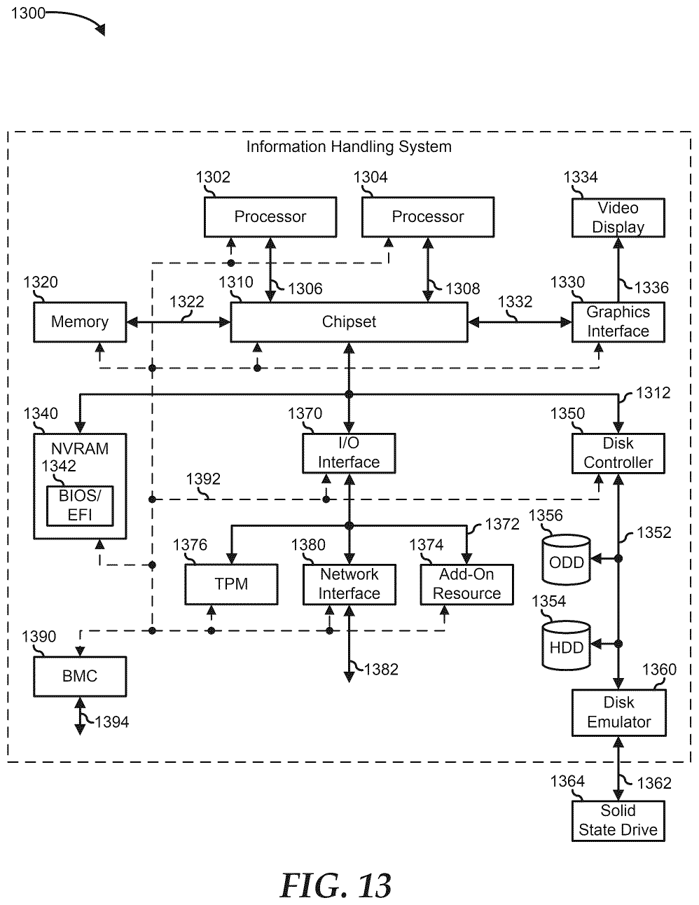

FIG. 1 shows a portion of an information handling system 100, which is similar to information handling system 1300 of FIG. 13, according to an embodiment of the present disclosure. In this example, information handling system 100 includes a circuit analyzer 130 and a PCB 110 that further includes a test coupon 120. Test coupon 120 may be configured to provide electrical communication to determine the backdrill quality of one or more backdrills, such as whether a backdrill is within specifications. For example, test coupon 120 may be configured to determine whether the backdrill is according to a pre-defined depth. Test coupon 120 may be disposed along an edge of PCB 110 as shown. However, test coupons can be arranged differently. In addition, a test coupon may also be provided at a stand-alone PCB. Test coupon 120 includes test points TP1, TP2, TP3, TP4, and TP5.

TP1 is a test point for an associated trace on a top metal layer of PCB 110 that is connected to a test via (“L1”). The test via is a plated through-hole via that connects to traces on a second, third, fourth, and fifth metal layers of PCB 110. The traces on each lower metal layer are connected to secondary vias (labeled “L2” for the second metal layer, etc.). Each of the secondary vias is plated through-hole vias that connect the traces on the associated metal layers to the top metal layer. On the top metal layer, each of the secondary vias is connected by traces to their associated test point (e.g., via “L2” is connected to test point “TP1” through the second metal layer, etc.)

In some embodiments, test points TP1, TP2, TP3, TP4, and TP5 may be formed on a surface of PCB 110, wherein each one of test points TP1, TP2, TP3, TP4, and TP5 may be plated with a conducting metal to provide a conductive connection. This allows test points TP1, TP2, TP3, TP4, and TP5 to be used to detect open or short conditions, such as by using a multimeter or a flying probe. For example, a first test probe of the multimeter may be in contact with TP1, and a second test probe may be in contact with TP2 to detect whether there is a short or open condition between L1 and L2. The second test probe may then be moved to L3 to determine if there is a short or open condition between L1 and L3, and so on until the second test probe is moved to be in contact with TP5. Other combinations than the aforementioned for testing short or open conditions may be used and deemed within the scope of the present disclosure. In another embodiment, a flying probe may be similarly utilized to detect open or short conditions.

Circuit analyzer 130 may be configured to analyze test results performed to detect short/open conditions and determine whether the test passed or failed. Circuit analyzer 130 may also be configured to determine an overall test result based on the test results of one or more open/short tests performed. In addition, circuit analyzer 130 may generate a test report based on the test results. The test report may indicate whether one or more backdrills of the PCB are according to specification, such as whether the backdrill is within a tolerance of a pre-defined depth. If one or more backdrills are according to the specification, then the quality of the backdrills may have been verified.

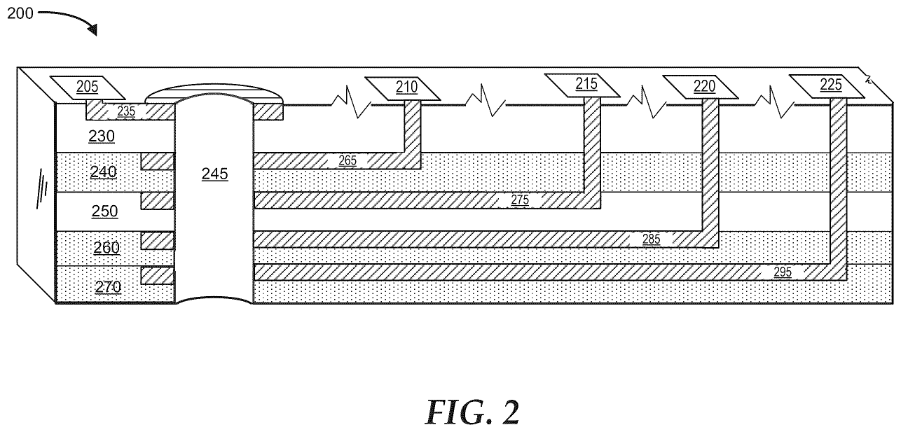

FIG. 2 shows a simplified cross-section of a portion of a PCB 200, which is similar to a portion of PCB 110 of FIG. 1, according to an embodiment of the present disclosure. In particular, PCB 200 may be a portion of test coupon 120 of PCB 110 of FIG. 1. PCB 200 includes layers 230, 240, 250, 260, and 270, and a via 245. PCB 200 also includes 235, 265, 275, 285, and 295 on the associated metal layers of layers 230, 240, 250, 260, and 270. In addition, PCB 200 includes test points 205, 210, 215, 220, and 225. In this example, test point 205 may correspond to TP1 of FIG. 1 while test point 210 may correspond to TP2 of FIG. 1. Further, test point 215 may correspond to TP3 of FIG. 1 while test point 220 may correspond to TP4 of FIG. 1 and test point 225 may correspond to TP5 of FIG. 1. Via 245 may correspond to via L1 of FIG. 1. Vias corresponding to L2, L3, L4, and L5 of FIG. 1 are not shown for simplicity.

Layers 230 and 250 may be conducting layers, also referred to as signal layers, while layer 240 is an isolating or ground layer, and layers 260 and 270 are isolating layers or ground/power layers. The isolating layers may be formed from a resin with a relative permittivity that electrically isolates layers 230 and 250 from each other, as conducting and isolating layers may alternate. Via 245 is a through hole via which is perpendicular to layers 230, 240, 250, 260, and 270. A wall of via 245 is plated with a conducting material often metallic, such as copper with desirable conductive properties, to form a conduction wall. Thus, via 245 may provide an electrical connection to one or more layers.

Test point 205 is associated with trace 235 while test point 210 is associated with trace 265. Test point 215 is associated with trace 275 while test point 220 is associated with trace 285 and test point 225 is associated with trace 295. Test points 205, 210, 215, 220, and 220 may be located on the surface along a topmost layer, such as layer 230. Traces 235, 265, 275, 285, and 295 run parallel to the aforementioned layers. In particular, trace 235 may be associated with layer 230 while trace 265 may be associated with layer 240. Trace 275 may be associated with layer 250 while trace 285 may be associated with layer 260 and trace 295 may be associated with layer 270.

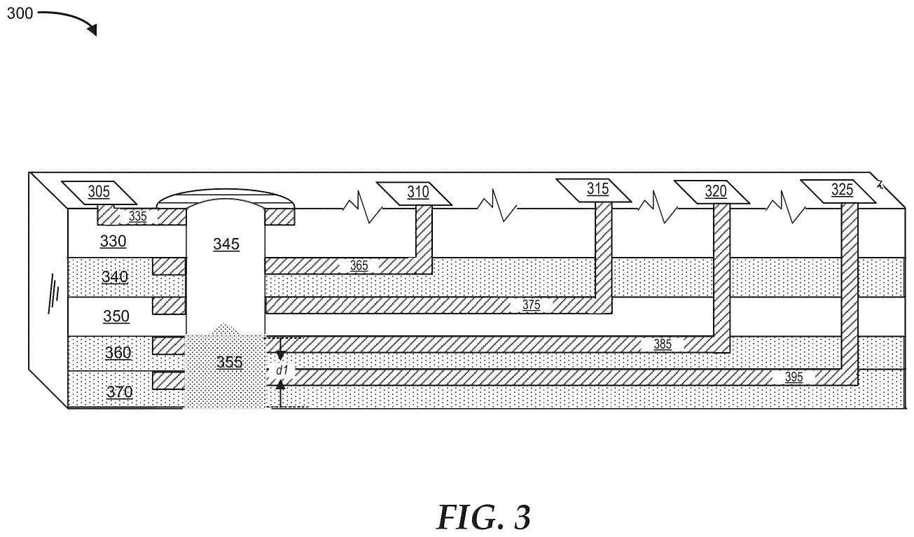

FIG. 3 shows a simplified cross-section of a portion of a PCB 300, which is similar to PCB 200 of FIG. 2, according to an embodiment of the present disclosure. PCB 300 includes layers 330, 340, 350, 360, and 370, a via 345, and a backdrill 355 with a depth of “d1.” Layer 330 is similar to layer 230 of FIG. 2 while layer 340 is similar to layer 240 of FIG. 2 and layer 350 is similar to layer 250 of FIG. 2. Layer 360 is similar to layer 260 of FIG. 2 while layer 370 is similar to layer 270 of FIG. 2 and via 345 is similar to via 245 of FIG. 2.

PCB 300 also includes traces 335, 365, 375, 385, and 395. Trace 335 is similar to trace 235 of FIG. 2 while trace 365 is similar to trace 265 of FIG. 2 and trace 375 is similar to trace 275 of FIG. 2. Trace 385 is similar to trace 285 of FIG. 2 and trace 395 is similar to trace 295 of FIG. 2. In addition, PCB 300 includes test points 305, 310, 315, 320, and 325. Test point 305 is similar to test point 205 of FIG. 2 while test point 310 is similar to test point 210 of FIG. 2 and test point 315 is similar to test point 215 of FIG. 2. Test point 320 is similar to test point 220 of FIG. 2 and test point 325 is similar to test point 225 of FIG. 2.

The design of PCB 300 may result in an unused portion of via 345 due to the lack of required connectivity among layers 360 and 370. The unused portion of via 345 may be referred to as a via stub. Via stubs can cause impedance discontinuities and reflections that may have a negative effect on the performance of a PCB. Negative effects include increased jitter, signal attenuation, as well as reduced noise margins. These unused portions may be removed by backdrilling with a mechanical drill bit thereby removing some via material resulting in a backdrill hole, as depicted by backdrill 355. Backdrill 355 may have a pre-defined properties provided by a specification, such as backdrill depth, width, etc. A backdrill hole may be simply referred to herein as a backdrill.

A backdrill hole depth, also referred to herein as backdrill depth, may allow for via material to be removed from PCB 300 and past each unused layer but not remove via material adjacent to a layer having a trace that requires electrical connectivity to the via. As a non-limiting example, backdrill 355 may be drilled from the bottom of PCB 200 up to layer 360. However, it should be pointed out that the backdrilling can occur from the upper surface of PCB 200. Due to the close tolerances of adjacent layers, the backdrilling process can remove excessive material than desired, thereby opening a circuit designed to be closed.

In other instances, the backdrilling process may result in a backdrill of an insufficient depth, wherein not enough via material is removed. This can leave at least a portion of the undesired via stub on the PCB, which can cause tests for short and/or open conditions to fail. Typical PCB manufacturing techniques are not able to properly determine whether a backdrilled hole has been drilled to its defined depth or width according to specification. In addition, the PCB manufacturing techniques typically also cannot detect PCB slivers. As such, the ability to verify backdrill quality, such as the backdrill is at the pre-defined depth and/or width provided by the present disclosure is desirable.

In one example, one or more short or open condition tests, also referred to herein as short or open tests may determine whether depth d1 of backdrill 355 is according to a pre-defined depth of the specification. The pre-defined depth would be removed via material from a surface of PCB 300 and past each unused layer, but not remove via material adjacent to a layer having a trace that requires electrical connectivity to the via. As a non-limiting example, if a particular via required connectivity between traces of layers 330 through 350, the desired pre-defined depth would extend from the surface of PCB 300 past layer 360 but not into layer 350.

The specification may also indicate which layers should be interconnected or shorted and which layers should be open. The test may then be performed to verify the connectivity indicated in the specification. For example, backdrill 355 may be specified to be drilled through layer 360. If backdrill 355 has been drilled as specified, then layers 330 and 340 should be interconnected. In addition, layers 330 and 350 should also be interconnected while layers 330 and 360 should not be connected nor are layers 330 and 370. Test coupon 120 of FIG. 1 may be configured to detect a short if two layers are interconnected and to detect an open condition if two layers are not connected via the test points. Thus, when tested for short or open, layers 330 and 340 should be shorted along with layers 330 and 350. However, layers 330 and 360 should be open along with layers 330 and 370.

In one example, a multimeter may be used to test if there is a short or open condition with corresponding layers of test points 305, 310, 315, 320, and 325. In another embodiment, a flying probe may be used instead of the multimeter. If any one of the tests fails, then there is a possibility that backdrill 355 has been drilled to an incorrect depth and/or width. A failing test may also indicate that a PCB sliver potentially exists. For example, if the PCB sliver is located in a section of layer 360 where the via material should be removed, the PCB sliver may short layer 360 with layer 350. In this example, depth d1 may be within tolerances of the pre-defined depth.

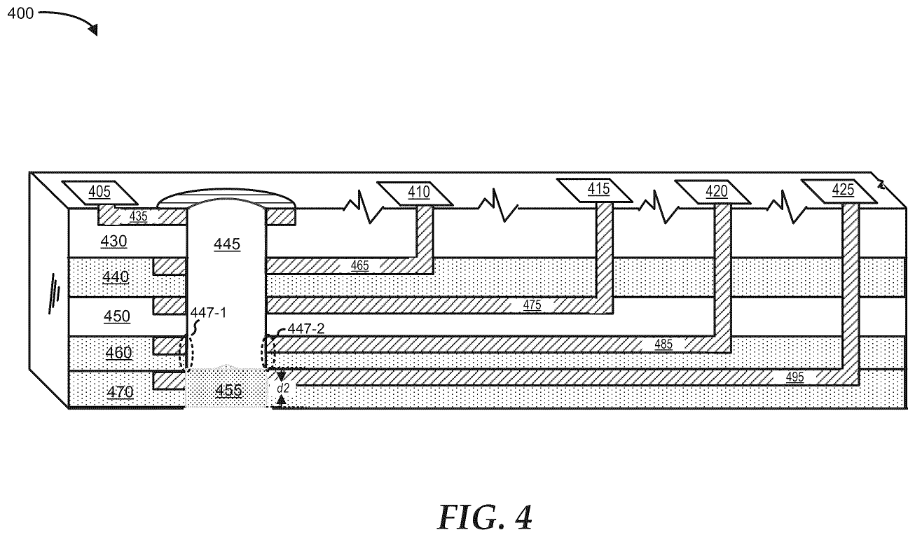

FIG. 4 shows a simplified cross-section of a portion of a PCB 400, which is similar to PCB 200 of FIG. 2 and PCB 300 of FIG. 3, according to an embodiment of the present disclosure. PCB 400 includes layers 430, 440, 450, 460, and 470, a via 445, and a backdrill 455 at a depth “d2”. Layer 430 is similar to layer 330 of FIG. 3 while layer 440 is similar to layer 340 of FIG. 3 and layer 450 is similar to layer 350 of FIG. 3. Layer 460 is similar to layer 360 of FIG. 3 while layer 470 is similar to layer 370 of FIG. 3 and via 445 is similar to via 345 of FIG. 3.

PCB 400 also includes traces 435, 465, 475, 485, and 495. Trace 435 is similar to trace 335 of FIG. 3 while trace 465 is similar to trace 365 of FIG. 3 and trace 475 is similar to trace 375 of FIG. 3. Trace 485 is similar to trace 385 of FIG. 3 and trace 495 is similar to trace 395 of FIG. 3. In addition, PCB 400 includes test points 405, 410, 415, 420, and 425. Test point 405 is similar to test point 305 of FIG. 3 while test point 410 is similar to test point 310 of FIG. 3 and test point 415 is similar to test point 315 of FIG. 3. Test point 420 is similar to test point 320 of FIG. 3 and test point 425 is similar to test point 325 of FIG. 3.

Backdrill 455 is similar to backdrill 355 of FIG. 3. However, depth “d2” of backdrill 455 may not be of the same depth as depth “d1” of backdrill 355 of FIG. 3, wherein backdrill 455 may be shallower than backdrill 355 of FIG. 3. For example, instead of removing via stub associated with layers 460 and 470, the backdrill operation removed the via stub associated with layer 470. Thus, leaving via material along layer 460 potentially creating via stripes 447-1 and 447-2. Accordingly, in this scenario, layers 430 and 460 may be interconnected. As such, test points 405 and 420 may indicate that layers 430 and 460 be shorted instead of being in an open condition. Thus, failing the open/short test. Because portions of via material associated with layer 460 should have been removed as indicated in the specification according to the pre-defined height, then depth d2 may be shallower than the pre-defined depth.

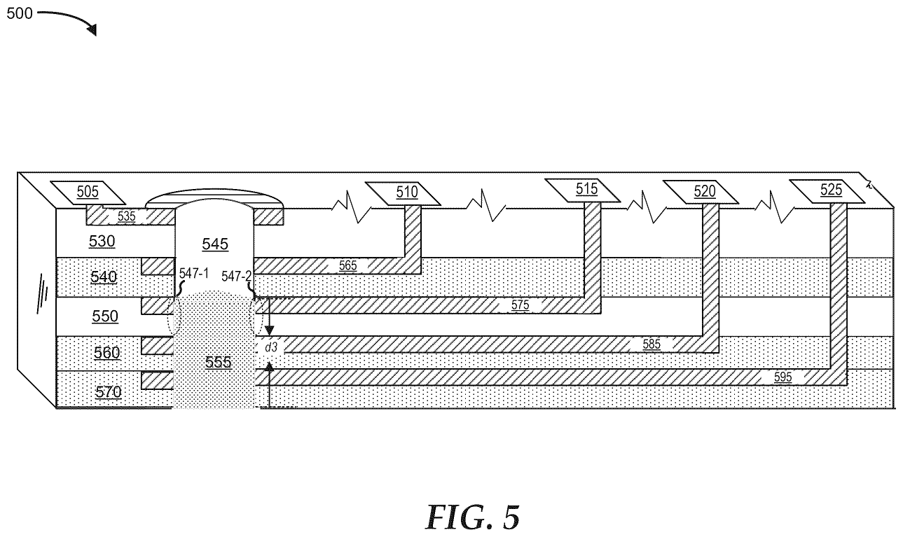

FIG. 5 shows a simplified cross-section of a portion of a PCB 500, which is similar to PCB 200 of FIG. 2 and PCB 300 of FIG. 3, according to an embodiment of the present disclosure. PCB 500 includes layers 530, 540, 550, 560, and 570, a via 545, and a backdrill 555 at depth “d3.” Layer 530 is similar to layer 330 of FIG. 3 while layer 540 is similar to layer 340 of FIG. 3 and layer 550 is similar to layer 350 of FIG. 3. Layer 560 is similar to layer 360 of FIG. 3 while layer 570 is similar to layer 370 of FIG. 3 and via 545 is similar to via 345 of FIG. 3.

PCB 500 also includes traces 535, 565, 575, 585, and 595. Trace 535 is similar to trace 335 of FIG. 3 while trace 565 is similar to trace 365 of FIG. 3 and trace 575 is similar to trace 375 of FIG. 3. Trace 585 is similar to trace 385 of FIG. 3 and trace 595 is similar to trace 395 of FIG. 3. In addition, PCB 500 includes test points 505, 510, 515, 520, and 525. Test point 505 is similar to test point 305 of FIG. 3 while test point 510 is similar to test point 310 of FIG. 3 and test point 515 is similar to test point 315 of FIG. 3. Test point 520 is similar to test point 320 of FIG. 3 and test point 525 is similar to test point 325 of FIG. 3.

Backdrill 555 is similar to backdrill 355 of FIG. 3 and backdrill 455 of FIG. 4. However, depth “d3” of backdrill 555 may not be of the same depth as backdrill 355 of FIG. 3 and backdrill 455 of FIG. 4, wherein the depth “d3” of backdrill 555 may be deeper than the depth “d1” of backdrill 355 of FIG. 3 and the depth “d2” of backdrill 455 of FIG. 4. For example, instead of removing via stub associated with layers 560 and 570, the backdrill operation may have also removed the via stub associated with layer 550. Thus, removing additional via material at sections 547-1 and 547-2. Accordingly, in this scenario, layers 530 and 540 may be interconnected. However, layers 530 and 550 may not be interconnected and have an open condition. As such, test points 505 and 510 may be in an open condition instead of being shorted. Thus, failing the open/short test. Because portions of via material associated with layer 550 should not have been removed as indicated in the specification according to the pre-defined height, then depth d3 may be deeper than the pre-defined depth.

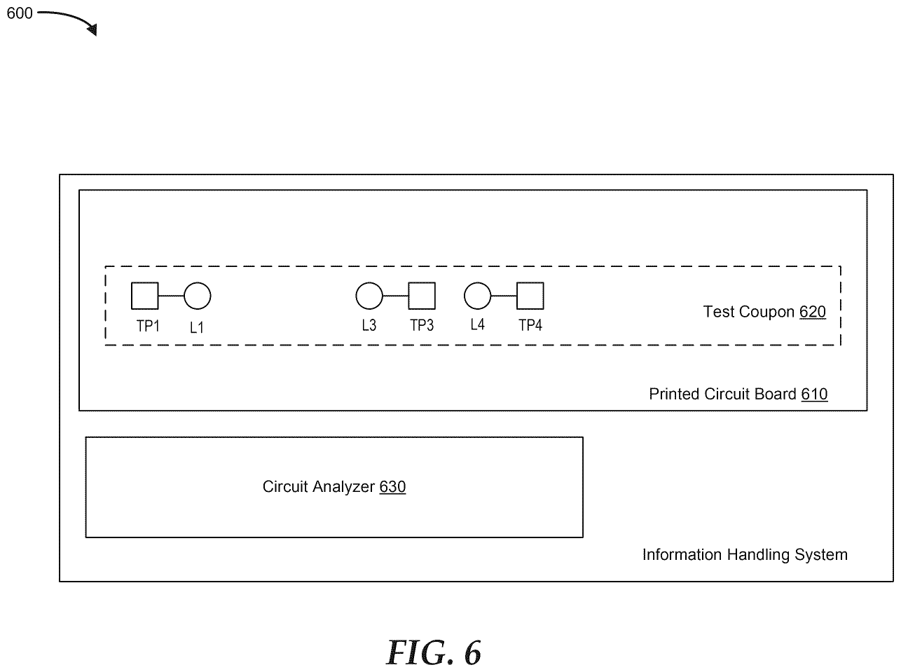

FIG. 6 shows a portion of an information handling system 600, which is similar to as information handling system 1300 of FIG. 13, according to an embodiment of the present disclosure. In this example, information handling system 600 includes a circuit analyzer 630 and a PCB 610 that further includes a test coupon 620. Circuit analyzer 630 is similar to circuit analyzer 130 of FIG. 1. PCB 610 is similar to PCB 110 of FIG. 1. In one example, PCB 610 can be a panel that includes a motherboard. Similar to test coupon 120 of FIG. 1, test coupon 620 may be configured to provide electrical communication to determine the backdrill quality of one or more backdrills, such as whether a backdrill is at a pre-defined depth. Test coupon 620 may be disposed along an edge of PCB 610 as shown. However, test coupons can be arranged differently. In addition, the test coupons may also be provided at a stand-alone PCB.

Test coupon 620 includes test points TP1, TP3, and TP4. TP1 is a test point for an associated trace on a top metal layer of PCB 610 that is connected to a test via (“L1”). The test via is a plated through-hole via that connects to traces on a second, third, fourth, and fifth metal layers of PCB 110. The trace of a lower metal layer is connected to a secondary via (labeled “L3” for the third metal layer and “L4” for the fourth metal layer). The secondary via is plated through-hole via that connects a trace to its associated test point. For example, via L3 is connected to test point TP3 and via L4 is connected to test point TP4.

In some embodiments, test points TP1, TP3, and TP4 may be formed on a surface of PCB 610, wherein each one of test points TP1, TP3, and TP4 may be plated with a conducting metal to provide a conductive connection. This allows test points TP1, TP3, and TP4 to be used to detect open or short conditions, also referred to simply as open/short conditions, such as by using a multimeter or a flying probe. For example, a first test probe of the multimeter may be in contact with TP1, and a second test probe may be in contact with TP3 to detect whether there is a short or open condition between L1 and L3.

In another test, the first test probe may be in contact with TP1, and the second test probe may be in contact with TP4 to detect whether there is a short or open condition between L1 and L4. Other combinations than the aforementioned for testing short or open conditions may be used and deemed within the scope of the present disclosure. For example, the first test probe may be in contact with TP3, and the second test probe may be in contact with TP4 to detect whether there is an open or short condition between L3 and L4. In another embodiment, a flying probe may be similarly utilized to detect the open or short conditions.

Circuit analyzer 630 may be configured to analyze test results performed to detect short/open conditions and determine whether the test passed or failed. Circuit analyzer 630 may also be configured to determine an overall test result based on the test results of one or more open/short tests performed. In addition, circuit analyzer 630 may generate a test report based on the test results. The test report may indicate whether one or more backdrills of the PCB are according to specification, such as whether the backdrill is within a tolerance of a pre-defined depth.

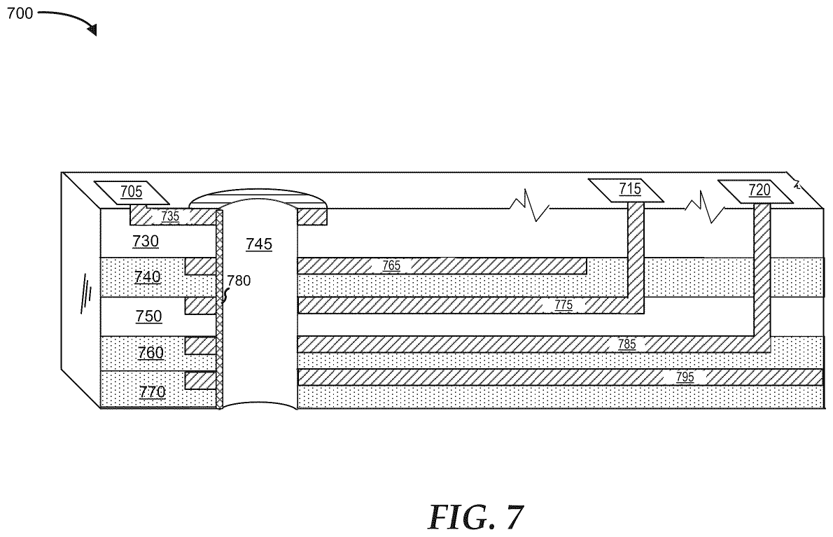

FIG. 7 shows a simplified cross-section of a portion of a PCB 700, which is similar to a portion of PCB 610 of FIG. 6, according to an embodiment of the present disclosure. In particular, PCB 700 may be a portion of test coupon 620 of PCB 610 of FIG. 6. PCB 700 includes layers 730, 740, 750, 760, and 770, and a via 745. PCB 700 also includes traces 735, 765, 775, 785, and 795. In addition, PCB 700 includes test points 705, 715, and 720. In this example, test point 705 may correspond to TP1 of FIG. 6 while test point 715 may correspond to TP3 of FIG. 6, and test point 720 may correspond to TP4 of FIG. 6. Via 745 may correspond to via L1 of FIG. 6. Via corresponding to L3 and L4 of FIG. 6 are not shown for simplicity.

Layers 730 and 740 may be conducting layers, also referred to as signal layers, while layer 740 is an isolating or ground layer, and layers 760 and 770 are isolating layers or ground/power layers. The isolating layers may be formed from a resin with a relative permittivity that electrically isolates layers 730 and 750 from each other, as conducting and isolating layers may alternate. Via 745 is a through hole via which is perpendicular to layers 730, 740, 750, 760, and 770. A wall of via 745 is plated with a conducting material often metallic, such as copper with desirable conductive properties, to form a conduction wall. Thus, via 745 may provide an electrical connection to one or more layers. Pad of via 745 may be grounded using layers 760 and 770 via a ground trace 780. A ground test may be used to verify whether layers are grounded according to specifications.

Test point 705 is associated with trace 735 while test point 715 is associated with trace 775 and test point 720 is associated with trace 785. Test points 705, 715, and 720 may be located on the surface along a topmost layer, such as layer 230. Traces 735, 765, 775, 785, and 795 run parallel to the aforementioned layers. In particular, trace 735 may be associated with layer 730 while trace 765 may be associated with layer 740. Trace 775 may be associated with layer 750 while trace 785 may be associated with layer 760 and trace 795 may be associated with layer 770.

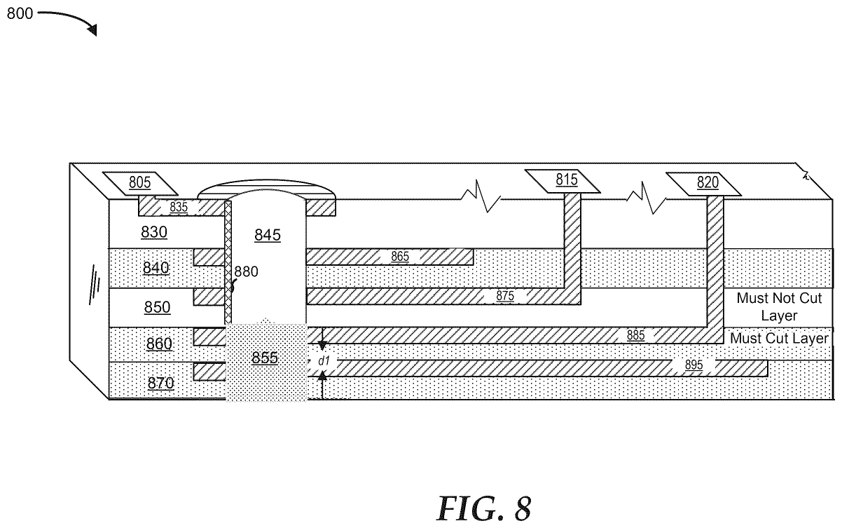

FIG. 8 shows a simplified cross-section of a portion of a PCB 800, which is similar to PCB 700 of FIG. 7, according to an embodiment of the present disclosure. PCB 800 includes layers 830, 840, 850, 860, and 870, a via 845, and a backdrill 855. Backdrill 855 may be drilled to a depth “d1.” Layer 830 is similar to layer 730 of FIG. 7 while layer 840 is similar to layer 740 of FIG. 7 and layer 850 is similar to layer 750 of FIG. 7. Layer 860 is similar to layer 760 of FIG. 7 while layer 870 is similar to layer 770 of FIG. 7 and via 845 is similar to via 745 of FIG. 7. PCB 800 also includes traces 835, 865, 875, 885, and 895. Trace 835 is similar to trace 735 of FIG. 7 while trace 865 is similar to trace 765 of FIG. 7 and trace 875 is similar to trace 775 of FIG. 7. Trace 885 is similar to trace 785 of FIG. 7 and trace 895 is similar to trace 795 of FIG. 7. In addition, PCB 800 includes test points 805, 815, and 820. Test point 805 is similar to test point 705 of FIG. 7 while test point 815 is similar to test point 715 of FIG. 7. Test point 820 is similar to test point 720 of FIG. 7.

Similar to PCB 700 of FIG. 7, the design of PCB 800 may result in an unused portion of via 845 due to the lack of required connectivity among layers 860 and 870. These unused portions may be removed by backdrilling, as depicted by backdrill 855. Backdrill 855 may have pre-defined properties provided by a specification, such as backdrill depth, width, etc. As a non-limiting example, based on the specification, backdrill 855 may be drilled from the bottom of PCB 800 up to layer 860 at certain mils in depth within a certain+/−tolerance in mils. However, it should be pointed out that the backdrilling can occur from the upper surface of PCB 800.

In one example, one or more tests, such as whether a particular layer is shorted to ground may be used to determine whether depth d1 of backdrill 855 is equal to the pre-defined depth or within the tolerance. In this example, the pre-defined depth in mils would include the removal of via material from a surface of PCB 800 and past each unused layer, but not remove the via material adjacent to a layer having a trace that requires electrical connectivity to the via. As a non-limiting example, if a particular via required connectivity between traces of layers 830 through 850, the desired pre-defined depth would extend from the surface of PCB 800 past layer 860 but not into layer 850.

In this example, a ground trace 880 may be a conductive strip that is configured to electrically couple a via pad to the ground/power layers of the PCB. This may provide a vertical ground reference. A test equipment may then be used to identify an open or a short circuit in the signal vias, traces, and/or pads of the PCB. If a short circuit is detected between a signal via, trace, and/or pad and the ground/power layer that should be in an open condition, then there is a probability that the backdrill is at an incorrect depth. Accordingly, if an open condition is detected between a signal via, trace, and/or pad and the ground/power layer that should be in shorted, then there is a probability that the backdrill is at an incorrect depth. A ground trace 880 may be configured to connect via pad associated with via 845 to ground/power layers 860 and/or 870. Accordingly, ground trace 880 may be utilized in detecting the short and open conditions. A short condition may also be referred to as a short circuit.

In a particular example, backdrill 855 may be specified to be drilled at the pre-defined depth through layer 860. Accordingly, layer 860 may be identified as a “must cut” layer that is reached by backdrill 855. Layer 850 may be identified as a “must not cut” layer that is above backdrill 855. In addition, layer 840 may also be identified as a “must not cut” layer based on dielectric thickness. As such, a first test probe of the test equipment may be put in contact with test point 805 and a second test probe in contact with test point 815 to determine whether layer 830 is shorted with layer 850. The second test probe may be moved and put in contact with test point 820 to determine whether layer 830 and layer 860 are in an open condition. The layers may be shorted if an impedance value measured during the testing is negligible and considered to be equal to zero ohms. The test equipment used may be a multimeter or a flying probe. A test to measure impedance between test points may also be used to determine whether there is a short circuit between the test points.

If test points 805 and 815 are shorted and test points 805 and 820 are in an open condition, then the test may confirm that a depth d1 of backdrill 855 is at the pre-defined depth or within the tolerance. Otherwise, then backdrill 855 may not have been drilled at the pre-defined depth or outside of the tolerance. In this example, backdrill 855 may have been drilled through layer 860 but not through layer 850. As such, backdrill 855 may have been drilled according to the pre-defined depth. Accordingly, test points 805 and 815 may be shorted. In addition, test points 805 and 820 may be in an open condition, passing the test. As such, the tests may verify that depth d1 of backdrill 855 is at the pre-defined depth.

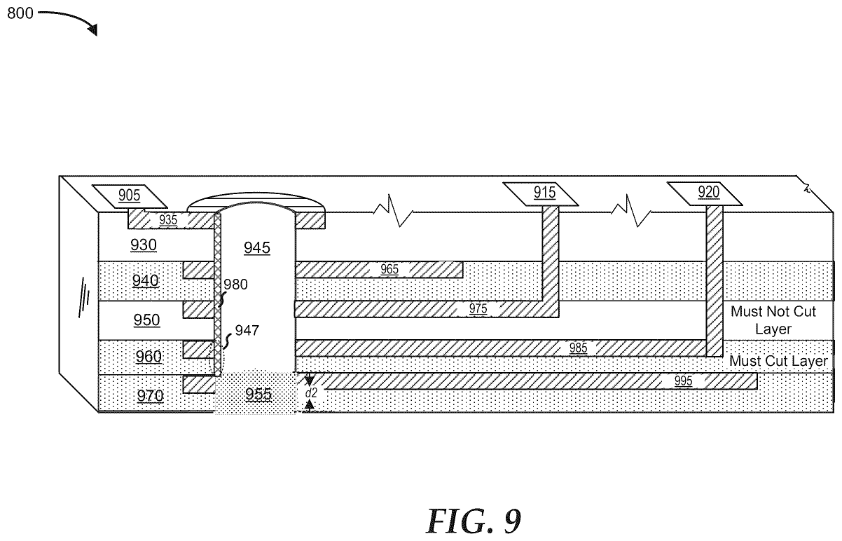

FIG. 9 shows a simplified cross-section of a portion of a PCB 900, which is similar to PCB 700 of FIG. 7 and PCB 800 of FIG. 8, according to an embodiment of the present disclosure. PCB 900 includes layers 930, 940, 950, 960, and 970, a via 945, and a backdrill 955. Backdrill 955 may be drilled to a depth “d2.” Layer 930 is similar to layer 830 of FIG. 8 while layer 940 is similar to layer 840 of FIG. 8 and layer 950 is similar to layer 850 of FIG. 8. Layer 960 is similar to layer 860 of FIG. 8 while layer 970 is similar to layer 870 of FIG. 8 and via 945 is similar to via 845 of FIG. 8. PCB 900 also includes traces 935, 965, 975, 985, and 995. Layer 950 may be a “must not cut” layer while layer 960 may be a “must cut” layer. In addition, layer 940 may also be a “must not cut” layer based on the dielectric thickness.

Trace 935 is similar to trace 835 of FIG. 8 while trace 965 is similar to trace 865 of FIG. 8 and trace 975 is similar to trace 875 of FIG. 8. Trace 985 is similar to trace 885 of FIG. 8 and trace 995 is similar to trace 895 of FIG. 8. In addition, PCB 900 includes test points 905, 915, and 920. Test point 905 is similar to test point 805 of FIG. 8 while test point 915 is similar to test point 815 of FIG. 8 and test point 920 is similar to test point 820 of FIG. 8.

As a non-limiting example, based on the specification, backdrill 955 may be drilled from the bottom of PCB 900 up to layer 960 at depth d2 at a pre-defined depth in mils. However, it should be pointed out that the backdrilling can occur from the upper surface of PCB 900. In one example, one or more tests, such as whether a particular layer is grounded may be used to determine whether a depth “d2” of backdrill 955 is according to the pre-defined depth. A test to measure impedance between test points may also be used to determine whether there is a short circuit between the test points.

In this example, backdrill 955 may have been drilled through layer 970 but not through layer 960. Accordingly, a section 947 of ground trace 980 that should have been removed may remain. As such, depth d2 of backdrill 955 may be shallower than depth d1 of backdrill 855 of FIG. 8. In this scenario, test points 905 and 915 may be shorted. In addition, test points 905 and 920 may also be shorted, failing the test. As such, depth d2 of backdrill 955 may not be drilled according to the pre-defined depth.

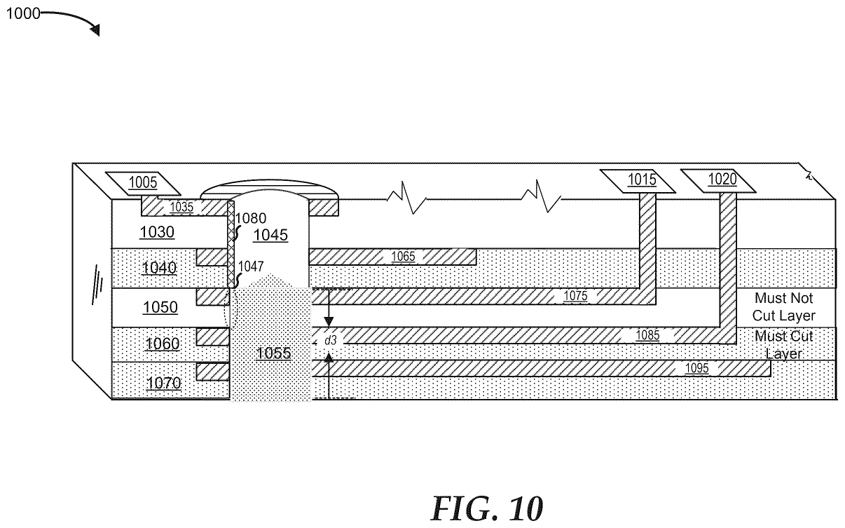

FIG. 10 shows a simplified cross-section of a portion of a PCB 1000, which is similar to PCB 700 of FIG. 7 and PCB 800 of FIG. 8, according to an embodiment of the present disclosure. PCB 1000 includes layers 1030, 1040, 1050, 1060, and 1070, a via 1045, and a backdrill 1055. Backdrill 1055 may be drilled to a depth “d3.” Layer 1030 is similar to layer 1030 of FIG. 8 while layer 1040 is similar to layer 840 of FIG. 8 and layer 1050 is similar to layer 850 of FIG. 8. Layer 1060 is similar to layer 860 of FIG. 8 while layer 1070 is similar to layer 870 of FIG. 8 and via 1045 is similar to via 845 of FIG. 8. Layer 1050 may be a “must not cut” layer while layer 1060 may be a “must cut” layer. In addition, layer 1040 may also be a “must not cut” layer based on the dielectric thickness.

PCB 1000 also includes traces 1035, 1065, 1075, 1085, and 1095. Trace 1035 is similar to trace 835 of FIG. 8 while trace 1065 is similar to trace 865 of FIG. 8 and trace 1075 is similar to trace 875 of FIG. 8. Trace 1085 is similar to trace 885 of FIG. 8 and trace 1095 is similar to trace 895 of FIG. 8. In addition, PCB 1000 includes test points 1005, 1015, and 1020. Test point 1005 is similar to test point 805 of FIG. 8 while test point 1015 is similar to test point 815 of FIG. 8 and test point 1020 is similar to test point 820 of FIG. 8.

As a non-limiting example, based on the specification, backdrill 1055 may be drilled from the bottom of PCB 1000 up to layer 960 at depth d3. However, it should be pointed out that the backdrilling can occur from the upper surface of PCB 1000. In one example, one or more open/short tests may be used to determine whether a depth d3 of backdrill 1055 has been drilled at the pre-defined depth. A test to measure impedance between test points may also be used to determine whether there is a short circuit between test points. In this example, backdrill 1055 may have been drilled through layer 1050. Accordingly, a section 1047 of ground trace 1080 that should have remained was removed. As such, the grounding of layer 1050 provided by ground trace 1080 may no longer exist. As such, depth d3 of backdrill 1055 may be deeper than depth d1 of backdrill 855 of FIG. 8. In this scenario, test points 1005 and 1015 may be in an open condition. In addition, test points 1005 and 1020 may also be in an open condition, failing the test. As such, depth d3 may be deemed to be an incorrect depth.

The number of test coupons and test points shown are not intended to be exhaustive but rather are representative to highlight components that can be utilized to implement aspects of the present disclosure. One of skill in the art will appreciate that the PCBs may have different number of traces and test points than shown herein. Although not all of the traces and/or layer shown has an associated test point, one of skill in the art will appreciate that the diagram explains a typical example, which can be extended in practice. The depicted example does not convey or imply any architectural or other limitations with respect to the presently described embodiments and/or the general disclosure. In the discussion of the figures, reference may also be made to components illustrated in other figures for continuity of the description.

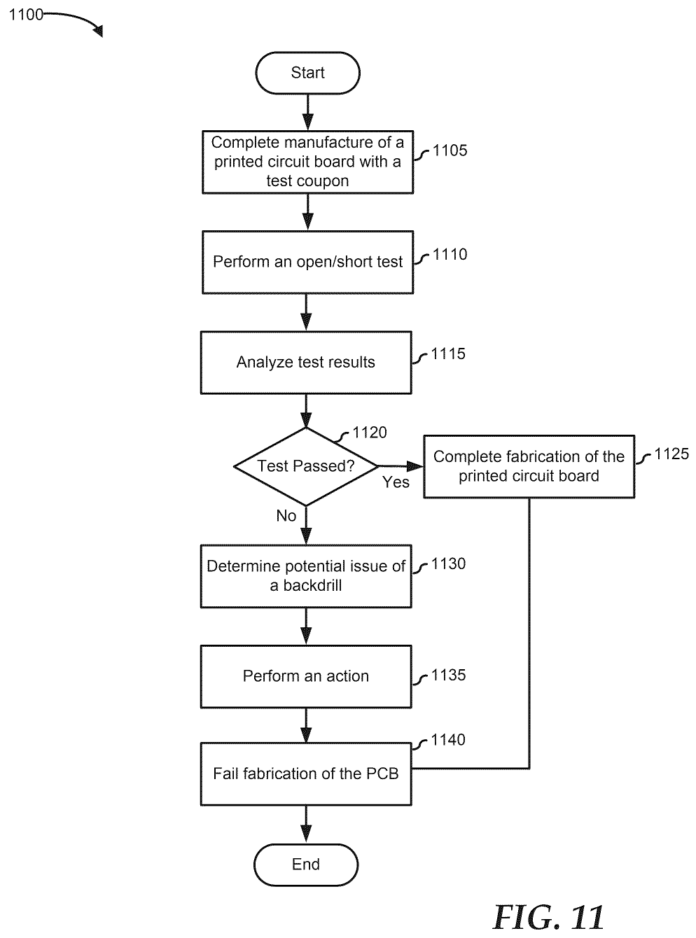

FIG. 11 shows a flowchart of a method 1100 for printed circuit board backdrill quality verification, according to an embodiment. Method 1100 may be employed in whole, or in part, by any other type of controller, device, module, processor, or any combination thereof, operable to employ all, or portions of method 1100. One of skill in the art will appreciate that this sequence diagram explains a typical example, which can be extended to applications or services in practice. In addition, it will be readily appreciated that not every method step set forth in this flow diagram is always necessary and that certain steps of the methods may be combined, performed simultaneously, in a different order, or perhaps omitted, without varying from the scope of the disclosure.

At block 1105, a PCB manufacture with at least one test coupon is completed. The PCB may be associated with an information handling system. The PCB manufactured may be similar to PCB 110 of FIG. 1. In an example, the PCB manufacture of the PCB may include any state of the PCB, such as before components are added to the surface of the PCB. The PCB may include multiple metal layers and each set of adjacent metal layers may be separated by respective insulating layers. The PCB may also include one or more vias and the via may result in a via stub. The via stub may impact the signal integrity of high-speed signal within the PCB. As such, the PCB may include one or more backdrilled holes to remove extra metal from the via according to a specification.

At block 1110, a test may be performed via the test coupon to determine backdrill quality based on short or open conditions. In an example, a first test probe of a multimeter may be positioned to be in contact with a first test point of the test coupon and a second test probe of the multimeter may be positioned to be in contact with a second test point of the test coupon to test for short or open condition. The test for the short or open condition may be performed on each combination of test points as applicable. For example, the second test probe of the multimeter may be moved to each one of the other test points to test for short or open conditions relative to the first test point. In another embodiment, a flying probe may be used to perform the test for short or open conditions.

At block 1115, the test results for each one of the short/open tests performed in block 1110 are analyzed. For example, a software application, such as a circuit analyzer may be associated with the test coupon, multimeter, and/or included with the information handling system. However, the circuit analyzer may be remote from the PCB and/or information handling system. In another embodiment, the circuit analyzer may be associated with the flying probe. In yet another embodiment, the analysis may be manually performed by a tester. The overall test operation passes if each one of the short/open tests passes as expected, wherein the backdrill is within a pre-defined depth and/or width according to a specification. Otherwise, the overall test operation fails.

At decision block 1120, if the overall test operation passed, then the “YES” branch is taken, and the method proceeds to block 1125. If the overall test operation fails, then the “NO” branch is taken, and the method proceeds to block 1130. At block 1125, the backdrill quality verification is complete. Accordingly, fabrication or manufacture of the printed circuit board in a quantity needed or desired by the PCB manufacturer may proceed. For example, when the overall test passes, then hundreds if not thousands or more of the PCBs may be manufactured. Afterwards, the method ends.

At block 1130, one or more actions, such as determining a potential issue of the backdrill may be identified. For example, based on which combination of test points failed the short/open test. In particular, the test failure may identify whether the backdrill is shallower or deeper than the pre-defined backdrill depth according to the specification. An action, such as a resolution to the issue may be determined. For example, if the backdrill is shallower than the desired depth, then a recommendation to drill the backdrill further to reach the desired depth may be provided.

At block 1135, a notification, such as a test report providing information associated with the backdrill quality may be generated. In addition, the notification or test report may be stored in memory. The notification or test report may include the resolution. At block 1140, the method may fail the overall test and does not proceed with the PCB fabrication or manufacture. Afterwards, the method ends.

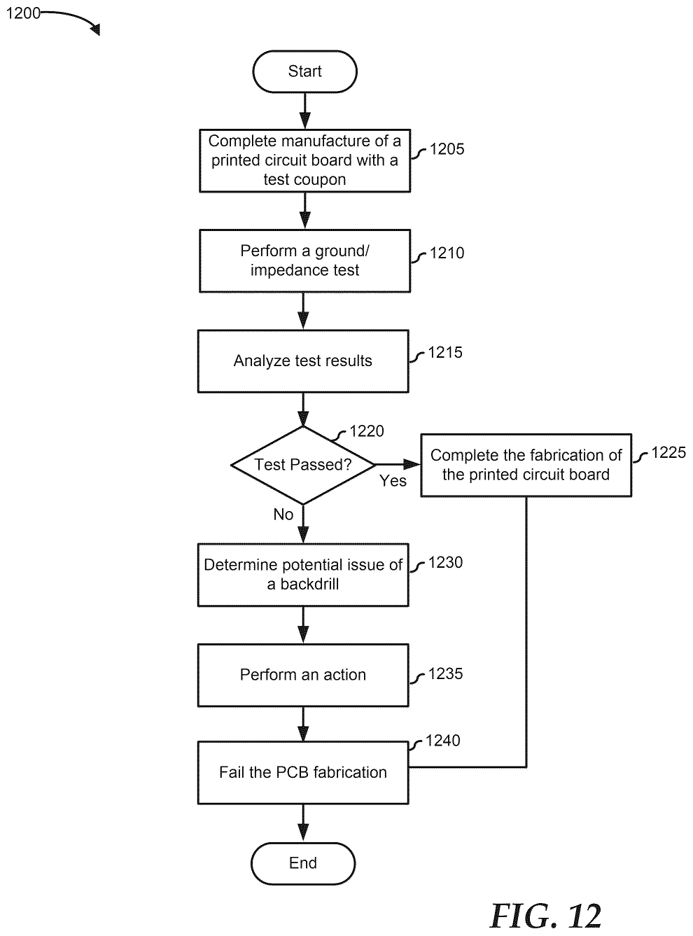

FIG. 12 shows a flowchart of a method 1200 for printed circuit board backdrill quality verification, according to an embodiment. Method 1200 may be employed in whole, or in part, by any other type of controller, device, module, processor, or any combination thereof, operable to employ all, or portions of method 1200. One of skill in the art will appreciate that this sequence diagram explains a typical example, which can be extended to applications or services in practice. In addition, it will be readily appreciated that not every method step set forth in this flow diagram is always necessary and that certain steps of the methods may be combined, performed simultaneously, in a different order, or perhaps omitted, without varying from the scope of the disclosure.

At block 1205, a PCB manufacture with at least one test coupon is completed. The PCB may be associated with an information handling system. The PCB manufactured may be similar to PCB 610 of FIG. 6. In an example, the PCB manufacture of the PCB may include any state of the PCB, such as before components are added to the surface of the PCB. The PCB may include multiple metal layers and each set of adjacent metal layers may be separated by respective insulating layers. The PCB may also include one or more vias and the via may result in a via stub. The via stub may impact the signal integrity of high-speed signal within the PCB. As such, the PCB may include one or more backdrilled holes to remove extra metal from the via according to a specification.

At block 1210, a test may be performed via the test coupon to determine backdrill quality based on short or open conditions. In an example, a first test probe of a multimeter may be positioned to be in contact with a first test point of the test coupon and a second test probe of the multimeter may be positioned to be in contact with a second test point of the test coupon to test for ground or impedance values. The test for the ground or impedance may be performed on each combination of test points as applicable. For example, the second test probe of the multimeter may be moved to each one of the other test points to test for ground or impedance values relative to the first test point. In another embodiment, a flying probe may be used to perform the test for ground or impedance values. If a short circuit between a signal via, trace, and/or pad and a ground/power plane is detected, then the backdrill may be of abnormal length or depth. Accordingly, if the impedance value measured during the test is in accordance with a pre-defined impedance value, then the test passes. Otherwise, the test fails.

At block 1215, the test results for each one of the short/open or impedance value tests performed in block 1210 are analyzed. For example, a software application, such as a circuit analyzer may be associated with the test coupon, multimeter, and/or included with the information handling system. However, the circuit analyzer may be remote from the PCB and/or information handling system. In another embodiment, the circuit analyzer may be associated with the flying probe. In yet another embodiment, the analysis may be manually performed by a tester. The overall test operation passes if each one of the short/open tests passes as expected, wherein the backdrill is within a pre-defined depth and/or width according to a specification. Otherwise, the overall test operation fails.

At decision block 1220, if the overall test operation passed, then the “YES” branch is taken, and the method proceeds to block 1225. If the overall test operation fails, then the “NO” branch is taken, and the method proceeds to block 1230. At block 1225, the backdrill quality verification is complete. Accordingly, fabrication or manufacture of the printed circuit board in a quantity needed or desired by the PCB manufacturer may be initiated or proceed. For example, hundreds if not thousands of the PCB may be manufactured or fabricated. Afterwards, the method ends.

At block 1230, one or more actions, such as determining a potential issue of the backdrill may be identified. For example, based on which combination of test points failed the short/open or impedance test. In particular, the test failure may identify whether the backdrill is shallower or deeper than the pre-defined backdrill depth according to the specification. An action, such as a resolution to the issue may be determined. For example, if the backdrill is shallower than the desired depth, then a recommendation to drill the backdrill further to reach the desired depth may be provided.

At block 1235, a notification, such as a report providing information associated with the backdrill quality in a test report. In addition, the notification or report may be stored in a memory. The notification or report may include the resolution. At block 1240, the method may fail the test. Accordingly, the PCB fabrication or manufacture may not be initiated. Afterwards, the method ends.

FIG. 13 illustrates an embodiment of an information handling system 1300 including processors 1302 and 1304, a chipset 1310, a memory 1320, a graphics adapter 1330 connected to a video display 1334, a non-volatile RAM (NVRAM) 1340 that includes a basic input and output system/extensible firmware interface (BIOS/EFI) module 1342, a disk controller 1350, a hard disk drive (HDD) 1354, an optical disk drive 1356, a disk emulator 1360 connected to a solid-state drive (SSD) 1364, an input/output (I/O) interface 1370 connected to an add-on resource 1374 and a trusted platform module (TPM) 1376, a network interface 1380, and a baseboard management controller (BMC) 1390. Processor 1302 is connected to chipset 1310 via processor interface 1306, and processor 1304 is connected to the chipset via processor interface 1308. In a particular embodiment, processors 1302 and 1304 are connected together via a high-capacity coherent fabric, such as a HyperTransport link, a QuickPath Interconnect, or the like. Chipset 1310 represents an integrated circuit or group of integrated circuits that manage the data flow between processors 1302 and 1304 and the other elements of information handling system 1300. In a particular embodiment, chipset 1310 represents a pair of integrated circuits, such as a northbridge component and a southbridge component. In another embodiment, some or all of the functions and features of chipset 1310 are integrated with one or more of processors 1302 and 1304.

Memory 1320 is connected to chipset 1310 via a memory interface 1322. An example of memory interface 1322 includes a Double Data Rate (DDR) memory channel and memory 1320 represents one or more DDR Dual In-Line Memory Modules (DIMMs). In a particular embodiment, memory interface 1322 represents two or more DDR channels. In another embodiment, one or more of processors 1302 and 1304 include a memory interface that provides a dedicated memory for the processors. A DDR channel and the connected DDR DIMMs can be in accordance with a particular DDR standard, such as a DDR3 standard, a DDR4 standard, a DDR5 standard, or the like.

Memory 1320 may further represent various combinations of memory types, such as Dynamic Random Access Memory (DRAM) DIMMs, Static Random Access Memory (SRAM) DIMMs, non-volatile DIMMs (NV-DIMMs), storage class memory devices, Read-Only Memory (ROM) devices, or the like. Graphics adapter 1330 is connected to chipset 1310 via a graphics interface 1332 and provides a video display output 1336 to a video display 1334. An example of a graphics interface 1332 includes a Peripheral Component Interconnect-Express (PCIe) interface and graphics adapter 1330 can include a four-lane (x4) PCIe adapter, an eight-lane (x8) PCIe adapter, a 16-lane (x16) PCIe adapter, or another configuration, as needed or desired. In a particular embodiment, graphics adapter 1330 is provided down on a system printed circuit board (PCB). Video display output 136 can include a Digital Video Interface (DVI), a High-Definition Multimedia Interface (HDMI), a DisplayPort interface, or the like, and video display 1334 can include a monitor, a smart television, an embedded display such as a laptop computer display, or the like.

NVRAM 1340, disk controller 1350, and I/O interface 1370 are connected to chipset 1310 via an I/O channel 1312. An example of I/O channel 1312 includes one or more point-to-point PCIe links between chipset 1310 and each of NVRAM 1340, disk controller 1350, and I/O interface 1370. Chipset 1310 can also include one or more other I/O interfaces, including a PCIe interface, an Industry Standard Architecture (ISA) interface, a Small Computer Serial Interface (SCSI) interface, an Inter-Integrated Circuit (I²C) interface, a System Packet Interface, a Universal Serial Bus (USB), another interface, or a combination thereof. NVRAM 1340 includes BIOS/EFI module 1342 that stores machine-executable code (BIOS/EFI code) that operates to detect the resources of information handling system 1300, to provide drivers for the resources, to initialize the resources, and to provide common access mechanisms for the resources. The functions and features of BIOS/EFI module 1342 will be further described below.

Disk controller 1350 includes a disk interface 1352 that connects the disc controller to a hard disk drive (HDD) 1354, to an optical disk drive (ODD) 1356, and to disk emulator 1360. An example of disk interface 1352 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 1360 permits SSD 1364 to be connected to information handling system 1300 via an external interface 1362. An example of external interface 1362 includes a USB interface, an institute of electrical and electronics engineers (IEEE) 1394 (Firewire) interface, a proprietary interface, or a combination thereof. Alternatively, SSD 1364 can be disposed within information handling system 1300.

I/O interface 1370 includes a peripheral interface 1372 that connects the I/O interface to add-on resource 1374, to TPM 1376, and to network interface 1380. Peripheral interface 1372 can be the same type of interface as I/O channel 1312 or can be a different type of interface. As such, I/O interface 1370 extends the capacity of I/O channel 1312 when peripheral interface 1372 and the I/O channel are of the same type, and the I/O interface translates information from a format suitable to the I/O channel to a format suitable to the peripheral interface 1372 when they are of a different type. Add-on resource 1374 can include a data storage system, an additional graphics interface, a network interface card (NIC), a sound/video processing card, another add-on resource, or a combination thereof. Add-on resource 1374 can be on a main circuit board, on separate circuit board, or add-in card disposed within information handling system 1300, a device that is external to the information handling system, or a combination thereof.

Network interface 1380 represents a network communication device disposed within information handling system 1300, on a main circuit board of the information handling system, integrated onto another component such as chipset 1310, in another suitable location, or a combination thereof. Network interface 1380 includes a network channel 1382 that provides an interface to devices that are external to information handling system 1300. In a particular embodiment, network channel 1382 is of a different type than peripheral interface 1372 and network interface 1380 translates information from a format suitable to the peripheral channel to a format suitable to external devices.

In a particular embodiment, network interface 1380 includes a NIC or host bus adapter (HBA), and an example of network channel 1382 includes an InfiniBand channel, a Fibre Channel, a Gigabit Ethernet channel, a proprietary channel architecture, or a combination thereof. In another embodiment, network interface 1380 includes a wireless communication interface, and network channel 1382 includes a Wi-Fi channel, a near-field communication (NFC) channel, a Bluetooth® or Bluetooth-Low-Energy (BLE) channel, a cellular based interface such as a Global System for Mobile (GSM) interface, a Code-Division Multiple Access (CDMA) interface, a Universal Mobile Telecommunications System (UMTS) interface, a Long-Term Evolution (LTE) interface, or another cellular based interface, or a combination thereof. Network channel 1382 can be connected to an external network resource (not illustrated). The network resource can include another information handling system, a data storage system, another network, a grid management system, another suitable resource, or a combination thereof.

BMC 1390 is connected to multiple elements of information handling system 1300 via one or more management interface 1392 to provide out of band monitoring, maintenance, and control of the elements of the information handling system. As such, BMC 1390 represents a processing device different from processor 1302 and processor 1304, which provides various management functions for information handling system 1300. For example, BMC 1390 may be responsible for power management, cooling management, and the like. The term BMC is often used in the context of server systems, while in a consumer-level device, a BMC may be referred to as an embedded controller (EC). A BMC included in a data storage system can be referred to as a storage enclosure processor. A BMC included at a chassis of a blade server can be referred to as a chassis management controller and embedded controllers included at the blades of the blade server can be referred to as blade management controllers. Capabilities and functions provided by BMC 1390 can vary considerably based on the type of information handling system. BMC 1390 can operate in accordance with an Intelligent Platform Management Interface (IPMI). Examples of BMC 1390 include an Integrated Dell® Remote Access Controller (IDRAC).

Management interface 1392 represents one or more out-of-band communication interfaces between BMC 1390 and the elements of information handling system 100, and can include an Inter-Integrated Circuit (I²C) bus, a System Management Bus (SMBUS), a Power Management Bus (PMBUS), a Low Pin Count (LPC) interface, a serial bus such as a Universal Serial Bus (USB) or a Serial Peripheral Interface (SPI), a network interface such as an Ethernet interface, a high-speed serial data link such as a PCIe interface, a Network Controller Sideband Interface (NC-SI), or the like. As used herein, out-of-band access refers to operations performed apart from a BIOS/operating system execution environment on information handling system 1300, that is apart from the execution of code by processors 1302 and 1304 and procedures that are implemented on the information handling system in response to the executed code.

BMC 1390 operates to monitor and maintain system firmware, such as code stored in BIOS/EFI module 1342, option ROMs for graphics adapter 1330, disk controller 1350, add-on resource 1374, network interface 1380, or other elements of information handling system 1300, as needed or desired. In particular, BMC 1390 includes a network interface 1394 that can be connected to a remote management system to receive firmware updates, as needed or desired. Here, BMC 1390 receives the firmware updates, stores the updates to a data storage device associated with the BMC, and transfers the firmware updates to the NVRAM of the device or system that is the subject of the firmware update, thereby replacing the currently operating firmware associated with the device or system, and reboots information handling system, whereupon the device or system utilizes the updated firmware image.

BMC 1390 utilizes various protocols and application programming interfaces (APIs) to direct and control the processes for monitoring and maintaining the system firmware. An example of a protocol or API for monitoring and maintaining the system firmware includes a graphical user interface (GUI) associated with BMC 1390, an interface defined by the Distributed Management Taskforce (DMTF) (such as a Web Services Management (WSMan) interface, a Management Component Transport Protocol (MCTP) or, a Redfish® interface), various vendor defined interfaces (such as a Dell EMC Remote Access Controller Administrator (RACADM) utility, a Dell EMC OpenManage Enterprise, a Dell EMC OpenManage Server Administrator (OMSA) utility, a Dell EMC OpenManage Storage Services (OMSS) utility, or a Dell EMC OpenManage Deployment Toolkit (DTK) suite), a BIOS setup utility such as invoked by a “F2” boot option, or another protocol or API, as needed or desired.

In a particular embodiment, BMC 1390 is included on a main circuit board (such as a baseboard, a motherboard, or any combination thereof) of information handling system 1300 or is integrated onto another element of the information handling system such as chipset 1310, or another suitable element, as needed or desired. As such, BMC 1390 can be part of an integrated circuit or a chipset within information handling system 1300. An example of BMC 1390 includes an iDRAC, or the like. BMC 1390 may operate on a separate power plane from other resources in information handling system 100. Thus, BMC 1390 can communicate with the management system via network interface 1394 while the resources of information handling system 1300 are powered off. Here, information can be sent from the management system to BMC 1390 and the information can be stored in a RAM or NVRAM associated with the BMC. Information stored in the RAM may be lost after power-down of the power plane for BMC 1390, while information stored in the NVRAM may be saved through a power-down/power-up cycle of the power plane for the BMC.

Information handling system 1300 can include additional components and additional busses, not shown for clarity. For example, information handling system 1300 can include multiple processor cores, audio devices, and the like. While a particular arrangement of bus technologies and interconnections is illustrated for the purpose of example, one of skill will appreciate that the techniques disclosed herein are applicable to other system architectures. Information handling system 1300 can include multiple central processing units (CPUs) and redundant bus controllers. One or more components can be integrated together. Information handling system 1300 can include additional buses and bus protocols, for example, I²C and the like. Additional components of information handling system 1300 can include one or more storage devices that can store machine-executable code, one or more communications ports for communicating with external devices, and various input and output (I/O) devices, such as a keyboard, a mouse, and a video display.

For purposes of this disclosure, information handling system 1300 can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 1300 can be a personal computer, a laptop computer, a smartphone, a tablet device or other consumer electronic device, a network server, a network storage device, a switch, a router, or another network communication device, or any other suitable device and may vary in size, shape, performance, functionality, and price. Further, information handling system 1300 can include processing resources for executing machine-executable code, such as processor 1302, a programmable logic array (PLA), an embedded device such as a System-on-a-Chip (SoC), or other control logic hardware. Information handling system 1300 can also include one or more computer-readable media for storing machine-executable code, such as software or data.

Although FIG. 11 and FIG. 12 show example blocks of method 1100 and method 1200 in some implementations, method 1100 and method 1200 may include additional blocks, fewer blocks, different blocks, or differently arranged blocks than those depicted in FIG. 11 and FIG. 12. Those skilled in the art will understand that the principles presented herein may be implemented in any suitably arranged processing system. Additionally, or alternatively, two or more of the blocks 1135 and 1140 of method 1100 may be performed in parallel.

In accordance with various embodiments of the present disclosure, the methods described herein may be implemented by software programs executable by a computer system. Further, in an exemplary, non-limited embodiment, implementations can include distributed processing, component/object distributed processing, and parallel processing. Alternatively, virtual computer system processing can be constructed to implement one or more of the methods or functionalities as described herein.

When referred to as a “device,” a “module,” a “unit,” a “controller,” or the like, the embodiments described herein can be configured as hardware. For example, a portion of an information handling system device may be hardware such as, for example, an integrated circuit (such as an Application Specific Integrated Circuit (ASIC), a Field Programmable Gate Array (FPGA), a structured ASIC, or a device embedded on a larger chip), a card (such as a Peripheral Component Interface (PCI) card, a PCI-express card, a Personal Computer Memory Card International Association (PCMCIA) card, or other such expansion card), or a system (such as a motherboard, a system-on-a-chip (SoC), or a stand-alone device).

The present disclosure contemplates a computer-readable medium that includes instructions or receives and executes instructions responsive to a propagated signal; so that a device connected to a network can communicate voice, video, or data over the network. Further, the instructions may be transmitted or received over the network via the network interface device.

While the computer-readable medium is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the methods or operations disclosed herein.

In a particular non-limiting, exemplary embodiment, the computer-readable medium can include a solid-state memory such as a memory card or other package that houses one or more non-volatile read-only memories. Further, the computer-readable medium can be a random-access memory or other volatile re-writable memory. Additionally, the computer-readable medium can include a magneto-optical or optical medium, such as a disk or tapes, or another storage device to store information received via carrier wave signals such as a signal communicated over a transmission medium. A digital file attachment to an e-mail or other self-contained information archive or set of archives may be considered a distribution medium that is equivalent to a tangible storage medium. Accordingly, the disclosure is considered to include any one or more of a computer-readable medium or a distribution medium and other equivalents and successor media, in which data or instructions may be stored.

Although only a few exemplary embodiments have been described in detail above, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents but also equivalent structures.

What is claimed is:

1. A printed circuit board, comprising:
a via configured to provide electrical connectivity between layers of the printed circuit board and having at least a portion of the via backdrilled resulting in a backdrill hole; and
a test coupon configured to determine whether the backdrill hole is according to a specification.

2. The printed circuit board of claim 1, wherein the specification includes a backdrill hole depth.

3. The printed circuit board of claim 1, wherein if the backdrill hole is according to the specification, then production of the printed circuit board is initiated.

4. The printed circuit board of claim 1, wherein the test coupon includes a test point.

5. The printed circuit board of claim 1, wherein a short/open test is used to determine whether the backdrill hole is according to a pre-defined backdrill hole depth.

6. The printed circuit board of claim 1, wherein a ground test is used to determine whether the backdrill hole is according to a pre-defined backdrill hole depth.

7. The printed circuit board of claim 1, wherein an impedance test is used to determine whether the backdrill hole is according to a pre-defined backdrill hole depth.

8. An information handling system comprising:
a printed circuit board comprising:
a via configured to provide electrical connectivity between layers of the printed circuit board and having at least a portion of the via backdrilled resulting in a backdrill hole; and
a test coupon configured to determine whether the backdrill hole is according to a specification.

9. The information handling system of claim 8, wherein the specification includes a backdrill hole depth.

10. The information handling system of claim 8, wherein if the backdrill hole is according to the specification, then production of the printed circuit board is initiated.

11. The information handling system of claim 8, wherein the test coupon includes a test point.

12. The information handling system of claim 8, wherein a short/open test is used to determine whether the backdrill hole is according to the specification.

13. The information handling system of claim 8, wherein a ground test is used to determine whether the backdrill hole is according to the specification.

14. The information handling system of claim 8, wherein an impedance test is used to determine whether the backdrill hole is according to the specification.

15. A method comprising:
providing a printed circuit board comprising:
a via providing electrical connectivity between layers of the printed circuit board and having at least a portion of the via backdrilled resulting in a backdrill hole; and
a test coupon providing electrical communication for determining whether the backdrill hole is according to a specification.

16. The method of claim 15, wherein the specification includes a backdrill hole depth.

17. The method of claim 15, wherein if the backdrill hole is according to the specification, then a short/open test passes.

18. The method of claim 15, wherein a short/open test is used to determine whether the backdrill hole is according to a pre-defined backdrill hole depth.

19. The method of claim 15, wherein a ground test is used to determine whether the backdrill hole is according to a pre-defined backdrill hole depth.

20. The method of claim 15, wherein an impedance test is used to determine whether the backdrill hole is according to a pre-defined backdrill hole depth.
